(19) United States
(12) Patent Application Publication
(10) Pub. No.: US 2022/0186896 A1
(43) Pub. Date: Jun. 16, 2022

(54) CANDLE LAMP CHARGING DEVICE AND CANDLE LAMP

(71) Applicant: Wenjing WU, Shenzhen (CN)

(72) Inventor: Wenjing WU, Shenzhen (CN)

(21) Appl. No.: 17/245,996

(22) Filed: Apr. 30, 2021

Related U.S. Application Data
(63) Continuation-in-part of application No. PCT/CN2020/136168, filed on Dec. 14, 2020.

(51) Int. Cl. F21S 9/03; F21V 23/06; F21S 10/04; H01L 31/0445; H01R 33/20

(52) U.S. Cl. CPC F21S 9/032; F21V 23/06; H01R 33/20; H01L 31/0445; F21S 10/043

(57) ABSTRACT

A candle lamp charging device and a candle lamp, the candle lamp charging device includes a housing, a light energy collection board and a charging connector; the housing is an accommodating cavity for accommodating the candle lamp, and a sidewall of the housing is provided with an opening configured for the candle lamp to enter and exit; the light energy collection board is disposed at the sidewall of the housing and facing a side away from the opening; the charging connector is convexly disposed at an inner surface of a bottom wall of the housing and electrically connected with the light energy collection board; a bottom of the candle lamp is provided with a charging interface for socketing on a charging connector, the candle lamp is provided therein with a rechargeable battery, a control circuit board and a light-emitting element.

### CROSS-REFERENCE TO RELATED APPLICATIONS

This application is a continuation-in-part of PCT International application PCT/CN2020/136168, filed on Dec. 14, 2020, the disclosure of which is hereby incorporated in its entirety by reference herein.

### TECHNICAL FIELD

The present application relates to the technical field of light energy utilization devices, and more particularly to a candle lamp charging device and a candle lamp.

### BACKGROUND

At present, the candle lamps sold on the market generally use three cylindrical batteries to supply power. The three cylindrical batteries can maintain for seven days. Such a huge amount of candle lamps will lead to huge battery consumption. In order to reduce environmental pollution, the used batteries are necessary to treat in a harmless manner, and a large number of used batteries will bring huge disposal costs.

### SUMMARY

An object of the present application is to provide a candle lamp charging device and a candle lamp, including but not limited to solve the technical problem that the candle lamp needs to be powered by disposable cylindrical batteries.

In order to solve above technical problem, the present application adopts the technical solution is providing a candle lamp charging device configured for charging a rechargeable battery built in the candle lamp, including:

a housing, provided therein with an accommodating cavity for accommodating the candle lamp, a sidewall of the housing is provided with an opening configured for the candle lamp to enter and exit, and the opening is in communication with the accommodating cavity;

a light energy collection board, disposed at the sidewall of the housing and facing a side away from the opening, and configured for converting an indoor light and sunlight into an electrical energy; and

a charging connector, convexly disposed at an inner surface of a bottom wall of the housing and electrically connected with the light energy collection board, and configured for plugging in the charging interface of the candle lamp.

In an embodiment, the housing is a non-transparent member.

In an embodiment, a distance from the charging connector to the opening is greater than or equal to a distance from the charging connector to the sidewall of the housing.

In an embodiment, the light energy collection board is a photoelectric conversion member made of amorphous silicon, monocrystalline silicon, polycrystalline silicon or copper indium gallium selenium material.

In an embodiment, a lighting area of the light energy collection board is greater than 30 square centimeters when the light energy collection board is the photoelectric conversion member made of amorphous silicon, monocrystalline silicon or polycrystalline silicon material.

In an embodiment, a lighting area of the light energy collection board is greater than 15 square centimeters when he light energy collection board is the photoelectric conversion member made of copper indium gallium selenium material.

In an embodiment, an included angle of 30 degrees to 90 degrees is formed between the light energy collection board and a horizontal plane.

In an embodiment, the charging device further includes:

a color-changing temperature-sensitive sheet, disposed at an inner surface of the sidewall of the housing.

The present application further provides a candle lamp, using the charging device above to charge the candle lamp, a bottom of the candle lamp is provided with a charging interface for socketing on a charging connector, the candle lamp is provided therein with a rechargeable battery, a control circuit board and a light-emitting element, and the charging interface, the rechargeable battery and the light-emitting element are electrically connected with the control circuit board, respectively.

In an embodiment, the control circuit board is provided with a voltage monitoring circuit, and the voltage monitoring circuit is in communication with the light-emitting element when the rechargeable battery reaches a preset voltage, such that the light-emitting element flashes at a preset frequency.

The beneficial effects of the candle lamp charging device provided by the embodiments of the present application are: the sidewall of the housing is provided with the light energy collection board and the charging connector is arranged in the accommodating cavity, such that the light energy is converted into electric energy through the light energy collection board, and then electric energy is supplied to the candle lamp through the charging connector, so that the built-in rechargeable battery of the candle lamp can be recharged when the power is insufficient, and it can be reused, thereby the technical problem that the candle lamp needs to be powered by a disposable cylindrical battery is solved, and the consumption of the cylindrical battery and the pressure on the environment are effectively reduced, and the candle lamp can be powered by renewable energy.

The beneficial effects of the candle lamp provided by the embodiments of the present application are: using a rechargeable battery instead of a disposable cylindrical battery as the power source of the light-emitting element, and connecting the charging interface with the charging connector of the charging device of the candle lamp to use the electric energy converting by the light energy collection board as the energy source for charging the rechargeable battery, thus solving the technical problem that the candle lamp needs to be powered by a disposable cylindrical battery, and the consumption of the cylindrical battery and the pressure on the environment are effectively reduced, and the use cost is reduced.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a schematic view of a use state of a candle lamp charging device provided by an embodiment of the present application;

FIG. 2 is a schematic front view of a candle lamp charging device provided by an embodiment of the present application;

FIG. 3 is a schematic transverse cross-sectional view of a candle lamp charging device provided by an embodiment of the present application;

FIG. 4 is a schematic longitudinal cross-sectional view of a candle lamp charging device provided by an embodiment of the present application;

FIG. 5 is a schematic longitudinal cross-sectional view of a candle lamp charging device provided by another embodiment of the present application;

FIG. 6 is a schematic longitudinal cross-sectional view of a candle lamp provided by an embodiment of the present application;

FIG. 7 is schematic diagram of a candle lamp provided by an embodiment of the present application.

In the drawings, the reference signs are listing as following:

1—candle lamp charging device; 2—candle lamp; 11—housing; 12—light energy collection board; 13—charging connector; 14—color—changing temperature—sensitive sheet; 20—charging interface; 100—accommodating cavity; 110—opening; 111—boss; 1110—inclined surface; W1—a distance from the charging connector to the opening; W2—a distance from the charging connector to a sidewall of the housing.

### DETAILED DESCRIPTION

In order to make the purpose, the technical solution and the advantages of the present application be clearer and more understandable, the present application will be further described in detail below with reference to accompanying figures and embodiments. It should be understood that the specific embodiments described herein are merely intended to illustrate but not to limit the present application.

It is noted that when a component is referred to as being “fixed to” or “disposed on” another component, it can be directly or indirectly on another component. When a component is referred to as being “connected to” another component, it can be directly or indirectly connected to another component. When a component referred to as being “electrically connected” with another component, it can be an electrical connection with a conductor, a radio connection, or various other connection methods that can transmit electrical signals. Terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn't be considered as any limitation to the present application. For those of ordinary skill in the art, the specific meaning of the above terms can be understood according to the specific situation. The terms “first” and “second” are only used for ease of description, and cannot be understood as indicating or implying relative importance or implicitly indicating the number of technical features. The meaning of “plurality” means two or more than two, unless otherwise specifically defined.

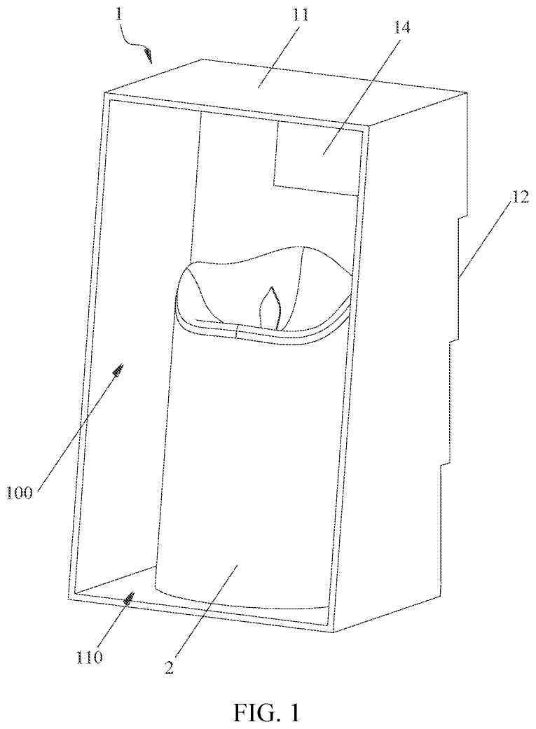

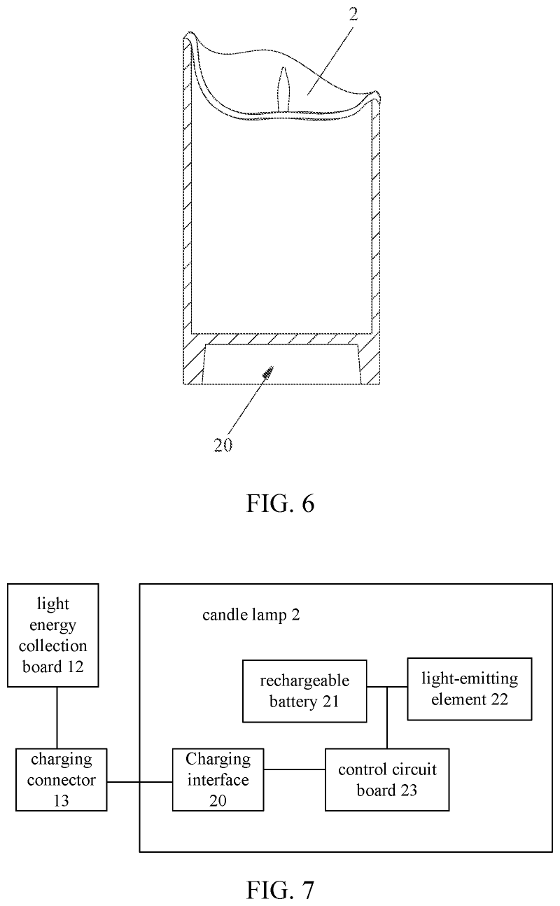

Please refer to FIGS. 1 to 6, the candle lamp charging device 1 configured for charging the rechargeable battery built in the candle lamp 2, which specifically includes a housing 11, a light energy collection board 12, and a charging connector 13, the housing is provided therein with accommodating cavity 100 for accommodating the candle lamp 2, and the sidewall of the housing 11 is provided with an opening 110 configured for the candle lamp 2 to enter and exit, the opening 110 is in communication with the accommodating cavity 100; the light energy collection board 12 is arranged on the sidewall of the housing 11, and the lighting surface of the light energy collection board 12 faces the side away from the opening 110, and is configured to convert indoor light and sunlight into electrical energy; the charging connector 13 is convexly arranged on the inner surface of the bottom wall of the housing 11, that is, the charging connector 13 protrudes from the bottom of the accommodating cavity 100 and is electrically connected to the light energy collection board 12 for plugging with the charging interface 20 of the candle lamp 2. It can be understood that a first conductive part is provided on the charging connector 13, and a second conductive part is provided in the charging interface 20. The first conductive part is electrically connected to the light energy collection board 12, and the second conductive part is electrically connected to the rechargeable battery. When the charging interface 20 is socketed on the charging connector 13, the first conductive part contacts and conducts with the second conductive part, so that the light energy collection board 12 supplies power to the rechargeable battery.

When the power of the candle lamp 2 is insufficient and needs to be charged, it is only necessary to place the candle lamp charging device 1 under the indoor light or on a window sill that can be irradiated by sunlight, and the lighting surface of the light energy collection board 12 is placed facing the light source, and then the candle lamp 2 is placed into the accommodating cavity 100 of the housing 11 from the opening 110, and the charging interface 20 is socketed on the charging connector 13 for a period of time to complete the charging of the built-in rechargeable battery of the candle lamp 2.

The candle lamp charging device 1 provided by the embodiment of the present application adopts that the sidewall of the housing 11 is provided with the light energy collection board 12 and the charging connector 13 is arranged in the accommodating cavity 100, such that the light energy is converted into electric energy through the light energy collection board 13, and then electric energy is supplied to the candle lamp 2 through the charging connector 13, so that the built-in rechargeable battery of the candle lamp 2 can be recharged when the power is insufficient, and it can be reused, thereby the technical problem that the candle lamp needs to be powered by a disposable cylindrical battery is solved, and the consumption of the cylindrical battery and the pressure on the environment are effectively reduced, and the candle lamp can be powered by renewable energy.

Further, as a specific embodiment of the candle lamp charging device provided in the present application, the housing 11 is a non-transparent member, that is, the housing 11 is made of non-transparent materials. Specifically, the outer contour of the housing 11 may be cylindrical or prismatic, and the accommodating cavity 100 is provided inside the housing 11. Except for the side where the opening 110 is located, the top and bottom sides of the accommodating cavity 100 and the side away from the opening 110 are closed, so when it is accommodated in the accommodating cavity 100, the candle lamp 2 is in a light-proof semi-enclosed space, and will not be irradiated by sunlight, thereby effectively prevents the wax layer of the candle lamp 2 from melting or the built-in rechargeable battery temperature is too high due to the sunlight, which is beneficial to prolong the service life of the candle lamp 2.

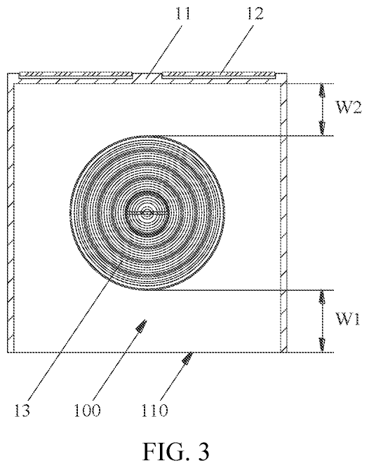

Further, please refer to FIGS. 3, 4, and 6, as a specific embodiment of the candle lamp charging device provided by the present application, the distance W1 from the charging connector 13 to the opening 110 is greater than or equal to the distance W2 from the charging connector 13 to the sidewall of the housing 11. That is, when the charging interface 20 is socketed on the charging connector 13, the overall position of the candle lamp 2 is close to the inner side of the accommodating cavity 100, which can further prevent the candle lamp 2 from being irradiated by sunlight during the charging process and reduce the risk that the wax layer of the candle lamp 2 will melt or the temperature of the built-in rechargeable battery will be too high due to the sunlight.

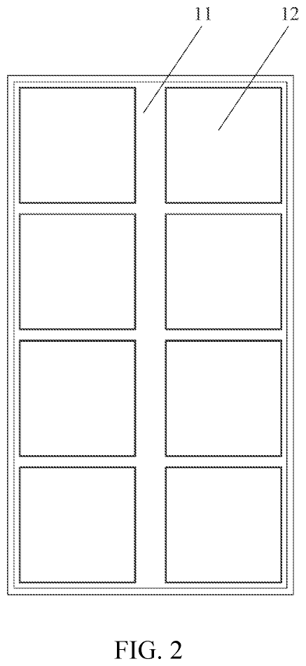

Further, please refer to FIG. 2, as a specific embodiment of the candle lamp charging device provided in this application, the light energy collection board 12 is a photoelectric conversion member made of amorphous silicon, monocrystalline silicon, polycrystalline silicon or copper indium gallium selenium material. Specifically, the light energy collection board 12 is a photoelectric semiconductor sheet made of amorphous silicon, monocrystalline silicon, polycrystalline silicon or copper indium gallium selenium (CIGS) materials, which can directly use light, sunlight, etc. to generate electricity. When the light energy collection board 12 is a photoelectric conversion member made of amorphous silicon, single crystal silicon or polysilicon materials, the lighting area of the light energy collection board 12 is greater than 30 square centimeters, that is, the surface area of the light energy collection board 12 exposed on the sidewall of the housing 11 should be greater than 30 square centimeters; when the light energy collection board 12 is a photoelectric conversion member made of copper indium gallium selenium material, the lighting area of the light energy collection board 12 is greater than 15 square centimeters, that is, the surface area of the light energy collection board 12 exposed on the sidewall of the housing 11 should be greater than 15 square centimeters, so as to ensure that the candle lamp 2 can work continuously (light up) for 4 to 8 hours after being charged for 8 hours. The specific experimental data can refer to the following table:

| | | lighting time | | |
|---|---|---|---|---|
| | | of the light | | Working |
| type of the light | lighting area of | energy | Average | hours of |
| energy collection | the light energy | collection | charging | candle |
| board | collection board | board | current | lamp |
| amorphous silicon, | 32 square | 8 hours | 3 mA | 4~8 hours |
| monocrystalline | centimeters | | | |
| silicon, poly- | | | | |
| crystalline silicon | | | | |
| copper indium | 16 square | 8 hours | 3 mA | 4~8 hours |
| gallium selenium | centimeters | | | |

It should be further explained that, from the above table, it can be concluded that the electricity converted by the light energy collection board 12 of the candle lamp charging device 1 in an indoor environment near a window is 0.003 Ampere*28800 seconds=86.4 Coulombs, and 86.4 Coulombs is the minimum total energy for the candle lamp 2 working 4-8 hours, if the lighting area of the light energy collection board 12 is lower than the above-mentioned area, the candle lamp 2 will not meet the usage standard. In fact, the light energy collecting technology under different environments, such as oblique indoor sunlight or direct sunlight outdoors, the energy collected by the light energy collection board 12 of the same area can differ by 100 times or more.

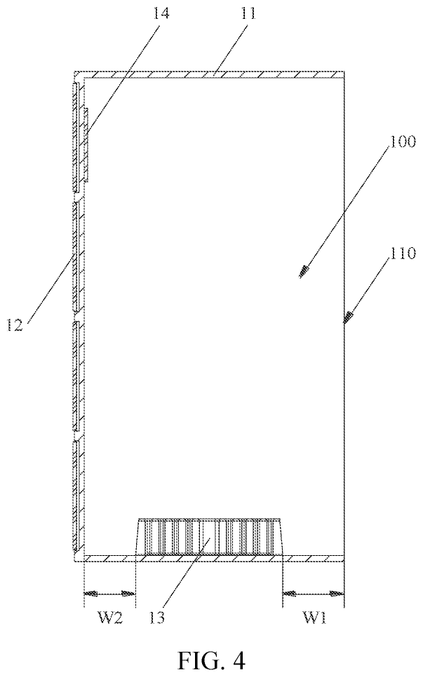

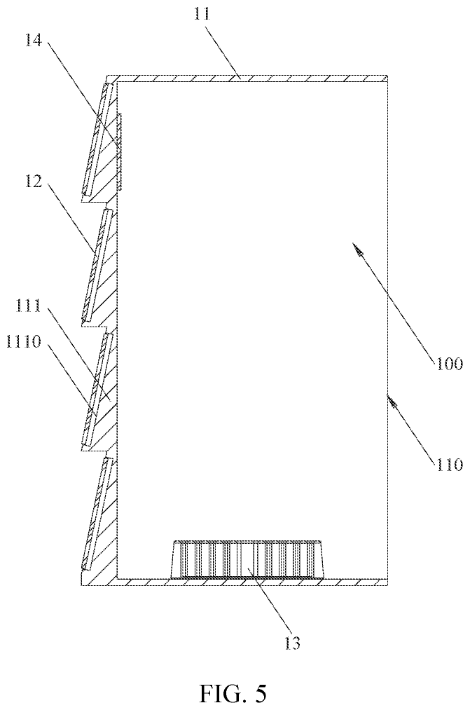

Further, please refer to FIGS. 4 and 5, as a specific embodiment of the candle lamp charging device provided by the present application, an included angle of 30 to 90 degrees is formed between the light energy collection board 12 and the horizontal plane. Specifically, the light energy collection board 12 may be directly pasted on the outer surface of the sidewall of the housing 11, or embedded in the outer surface of the side wall of the housing 11 through grooves provided at the sidewall of the housing 11. When the sidewall of the housing 11 has a surface extending in the vertical direction, as shown in FIG. 4, the light energy collection board 12 is arranged along the surface extending in the vertical direction and forms an angle of 90 degrees with the horizontal plane. When the sidewall of the housing 11 is provided with several bosses 111, the boss 111 has an inclined surface 1110 whose included angle with the horizontal plane is greater than or equal to 30 degrees and less than 90 degrees, as shown in FIG. 5, the light energy collection board 12 is arranged on the inclined surface 1110 and formed an included angle greater than or equal to 30 degrees and less than 90 degrees with the horizontal plane. In this way, under the included angle of 30 degrees to 90 degrees, the light energy collection board 12 can ensure a higher efficiency of collecting light energy, which is beneficial to maximize the photoelectric conversion efficiency.

Optionally, please refer to FIGS. 1, 4 and 5, as a specific embodiment of the candle lamp charging device provided by the present application, the candle lamp charging device 1 further includes a color-changing temperature-sensitive sheet 14, and the color-changing temperature-sensitive sheet 14 is arranged at the inner surface of the sidewall of the housing 11. Specifically, the color-changing temperature-sensitive sheet 14 is a sheet-like member made of temperature-sensitive materials that can repeatedly change color with changes in the ambient temperature. Because the temperature of the rechargeable battery built-in the candle lamp 2 will gradually change during the charging process. As the temperature rises, the air temperature in the accommodating cavity 100 also rises. By observing the temperature change of the color-changing temperature sensor 14, the user can intuitively distinguish the charging process of the candle lamp 2; and the color-changing temperature sensor 14 is arranged at the inner surface of the sidewall of the housing 11 and is located between the candle lamp 2 and the top wall of the housing 11, which can avoid being blocked by the candle lamp 2 in the charging process, which is convenient for users to watch and is beneficial to improve the user experience effect.

Please refer to FIGS. 1 and 6-7, the candle lamp 2 provided in the present application is charged by the above-mentioned candle lamp charging device 1. A charging interface 20 is provided at the bottom of the candle lamp 2 for socketing on the charging connector 13, and the candle lamp 2 is provided therein with a rechargeable battery 21, a control circuit board 23 and a light-emitting element 22. The charging interface 20, the rechargeable battery 21 and the light-emitting element 22 are respectively electrically connected to the control circuit board 23, and the candle lamp 2 controls the rechargeable battery 21 to charge and discharge and drive the light-emitting element 22 to emit light through the control circuit board 23.

The candle lamp 2 provided by the embodiment of the present application uses a rechargeable battery instead of disposable cylindrical batteries as the power source of the light-emitting element, and the electric energy converted from the light energy collection board 12 is used as the energy source for charging the rechargeable battery through the connecting of the charging interface 20 and the charging connector 13 of the candle lamp charging device 1, thereby the technical problem that the candle lamp needs to be powered by the disposable cylindrical batteries is solved, and the consumption of the cylindrical battery and the pressure on the environment are effectively reduced, and the use cost is reduced.

Optionally, as a specific embodiment of the candle lamp charging device provided in the present application, a voltage monitoring circuit is provided on the control circuit board, and when the rechargeable battery reaches a preset voltage, the voltage monitoring circuit is communicated to the light-emitting element to make the light-emitting element flash at a preset frequency. For example: the rechargeable battery is set to five levels of voltage. When charging is activated, the voltage of the rechargeable battery is at one level, at this time, the voltage monitoring circuit can control the light-emitting element to flash at the slowest frequency, indicating that the charging is activated, and so on. When the power of the rechargeable battery reaches 100%, the voltage of the rechargeable battery is in five levels. At this time, the voltage monitoring circuit can control the light-emitting element to flash at the fastest frequency, indicating that the charging is complete. In this way, according to different voltages corresponding to different flashing frequencies, the user can intuitively distinguish the charging process of the candle lamp 2.

The aforementioned embodiments are only preferred embodiments of the present application, and should not be regarded as being limitation to the present application. Any modification, equivalent replacement, improvement, and so on, which are made within the spirit and the principle of the present application, should be included in the protection scope of the present application.

What is claimed is:

1. A candle lamp charging device configured for charging a rechargeable battery built in the candle lamp, comprising:
a housing, provided therein with an accommodating cavity for accommodating the candle lamp, wherein a sidewall of the housing is provided with an opening configured for the candle lamp to enter and exit, and the opening is in communication with the accommodating cavity;
a light energy collection board, disposed at the sidewall of the housing and facing a side away from the opening, and configured for converting an indoor light and sunlight into an electrical energy; and
a charging connector, convexly disposed at an inner surface of a bottom wall of the housing and electrically connected with the light energy collection board, and configured for plugging in the charging interface of the candle lamp.

2. The charging device according to claim 1, wherein the housing is a non-transparent member.

3. The charging device according to claim 2, wherein a distance from the charging connector to the opening is greater than or equal to a distance from the charging connector to the sidewall of the housing.

4. The charging device according to claim 1, wherein the light energy collection board is a photoelectric conversion member made of amorphous silicon, monocrystalline silicon, polycrystalline silicon or copper indium gallium selenium material.

5. The charging device according to claim 4, wherein a lighting area of the light energy collection board is greater than 30 square centimeters when the light energy collection board is the photoelectric conversion member made of amorphous silicon, monocrystalline silicon or polycrystalline silicon material.

6. The charging device according to claim 4, wherein a lighting area of the light energy collection board is greater than 15 square centimeters when he light energy collection board is the photoelectric conversion member made of copper indium gallium selenium material.

7. The charging device according to claim 1, wherein an included angle of 30 degrees to 90 degrees is formed between the light energy collection board and a horizontal plane.

8. The charging device according to claim 1, wherein the charging device further comprises:
a color-changing temperature-sensitive sheet, disposed at an inner surface of the sidewall of the housing.

9. A candle lamp, using a charging device to charge the candle lamp, the charging device comprises:
a housing, provided therein with an accommodating cavity for accommodating the candle lamp, wherein a sidewall of the housing is provided with an opening configured for the candle lamp to enter and exit, and the opening is in communication with the accommodating cavity;
a light energy collection board, disposed at the sidewall of the housing and facing a side away from the opening, and configured for converting an indoor light and sunlight into electrical energy; and
a charging connector, convexly disposed at an inner surface of a bottom wall of the housing and electrically connected with the light energy collection board, and configured for plugging in the charging interface of the candle lamp;
wherein a bottom of the candle lamp is provided with a charging interface for socketing on a charging connector, the candle lamp is provided therein with a rechargeable battery, a control circuit board and a light-emitting element, and the charging interface, the rechargeable battery and the light-emitting element are electrically connected with the control circuit board, respectively.

10. The candle lamp according to claim 9, wherein the control circuit board is provided with a voltage monitoring circuit, the voltage monitoring circuit is in communication with the light-emitting element when the rechargeable battery reaches a preset voltage, such that the light-emitting element flashes at a preset frequency.

11. The candle lamp according to claim 9, wherein the housing is a non-transparent member.

12. The candle lamp according to claim 11, wherein a distance from the charging connector to the opening is greater than or equal to a distance from the charging connector to the sidewall of the housing.

13. The candle lamp according to claim 9, wherein the light energy collection board is a photoelectric conversion member made of amorphous silicon, monocrystalline silicon, polycrystalline silicon or copper indium gallium selenium material.

14. The candle lamp according to claim 13, wherein a lighting area of the light energy collection board is greater than 30 square centimeters when the light energy collection board is the photoelectric conversion member made of amorphous silicon, monocrystalline silicon or polycrystalline silicon material.

15. The candle lamp according to claim 13, wherein a lighting area of the light energy collection board is greater than 15 square centimeters when he light energy collection board is the photoelectric conversion member made of copper indium gallium selenium material.

16. The candle lamp according to claim 9, wherein an included angle of 30 degrees to 90 degrees is formed between the light energy collection board and a horizontal plane.

17. The candle lamp according to claim 9 wherein the charging device further comprises:
a color-changing temperature-sensitive sheet, disposed at an inner surface of the sidewall of the housing.
